(19) United States
(12) Patent Application Publication
(10) Pub. No.: US 2023/0318627 A1
(43) Pub. Date: Oct. 5, 2023

(54) SOFT-DECISION DECODING METHOD AND APPARATUS

(71) Applicant: Electronics and Telecommunications Research Institute, Daejeon (KR)

(72) Inventors: Seok Ki KIM, Daejeon (KR); Gi Yoon PARK, Daejeon (KR); Ok Sun PARK, Daejeon (KR); Young Joo LEE, Daejeon (KR); Chang Hyeon KIM, Daejeon (KR)

(73) Assignee: Electronics and Telecommunications Research Institute, Daejeon (KR)

(21) Appl. No.: 18/295,681

(22) Filed: Apr. 4, 2023

(30) Foreign Application Priority Data
Apr. 4, 2022 (KR) 10-2022-0041533

(51) Int. Cl. H03M 13/15; H03M 13/11; H03M 13/00

(52) U.S. Cl. CPC H03M 13/152; H03M 13/1111; H03M 13/611

(57) ABSTRACT

A soft-decision decoding method used in a digital communication system may comprise: using a hard-decision Bose-Chadhuri-Hocquenghem (BCH) decoder as a stopping rule of ordered statistic decoding (OSD) before performing the OSD on an input signal; and performing the OSD when a highest order of an error position equation generated in the BCH decoder is not equal to a number of solutions found in the BCH decoder.

### CROSS-REFERENCE TO RELATED APPLICATIONS

This application claims priority to Korean Patent Application No. 10-2022-0041533, filed on Apr. 4, 2022, with the Korean Intellectual Property Office (KIPO), the entire contents of which are hereby incorporated by reference.

### BACKGROUND

### 1. Technical Field

The present disclosure relates to a soft-decision decoding method and apparatus capable of implementing ultra-low latency by using a new ordered statistic decoding (OSD) algorithm applicable to a short error correction code.

### 2. Related Art

Noise represented by Gaussian noise is present in a channel through which data is transmitted and received, resulting in a high possibility of data mismatch between transmission data and received data. Thus, there are various error correction codes for improving reliability of transmission and received data.

There are a hard-decision algorithm and a soft-decision algorithm as algorithms for decoding an error correction code, and a maximum likelihood (ML) algorithm is representatively known as the soft-decision algorithm. For the ML algorithm, weighted hamming distances (WHDs) have to be compared for all codes, resulting in extremely high computational complexity and significant difficulty in practical use.

Meanwhile, as another soft-decision algorithm, an ordered statistic decoding (OSD) algorithm uses a reliability value of a random linear block code expressed as (N, K) to greatly reduce complexity while showing performance close to the ML algorithm, but there is still the problem of the exponential increase of the computational complexity with an increase of a code length. Recently, an enhanced OSD algorithm that reduces the computational complexity of the OSD algorithm has been proposed and has been used as one of decoding schemes applicable to an ultra-reliable and low-latency communications (URLLC) service of next-generation wireless communications.

However, Gaussian elimination, which essentially has to be performed in the enhanced OSD algorithm, requires excessively high time complexity, limiting the overall decoding time.

Such a conventional technology has greatly reduced its computational complexity recently but requires several thousands of cycles or more in a decoding process, needing further improvement to satisfy URLLC requirements, and in particular, the generation of a test error pattern (TEP) for candidate codeword calculation is essentially required in the decoding process, resulting in a limit to sufficiently satisfy the low-latency requirement.

### SUMMARY

The present disclosure is proposed to solve these problems and aims to provide a low-latency soft-decision decoding method and apparatus supporting an improved ordered statistic decoding (OSD) algorithm optimized for hardware.

The present disclosure also aims to provide a low-latency soft-decision decoding method and apparatus using a stopping rule with a Bose-Chadhuri-Hocquenghem (BCH) decoder at an input terminal of the apparatus based on the fact that latency time may be greatly reduced by executing a soft-decision BCH decoder before executing an OSD algorithm.

The present disclosure also aims to provide a low-latency soft-decision decoding method and apparatus based on improved Gaussian elimination which simultaneously performs sorting based on the fact that a matrix suitable for an OSD algorithm may be generated without loss of latency time by performing sorting simultaneously during the execution of Gaussian elimination through improvement of an existing architecture.

The present disclosure also aims to provide a low-latency soft-decision decoding method and apparatus configured to support a reprocessing process of an OSD algorithm, thereby significantly reducing latency time.

According to a first exemplary embodiment of the present disclosure, a soft-decision decoding method used in a digital communication system may comprise: using a hard-decision Bose-Chadhuri-Hocquenghem (BCH) decoder as a stopping rule of ordered statistic decoding (OSD) before performing the OSD on an input signal; and performing the OSD when a highest order of an error position equation generated in the BCH decoder is not equal to a number of solutions found in the BCH decoder.

The performing of the OSD may comprise: performing Gaussian elimination through a setup operation and an elimination operation, and the performing of the Gaussian elimination may comprise: finding K pivots in the setup operation and performing the Gaussian elimination in the elimination operation, wherein the elimination operation is performed after the setup operation.

The soft-decision decoding method may further comprise: arranging K rows required for the OSD by performing sorting through a sorter simultaneously during the elimination operation.

The soft-decision decoding method may further comprise: generating a test error pattern (TEP), wherein the generating of the TEP comprises a TEP of a target Hamming weight through a shift operation and an OR operation, the shift operation may comprise a 1-bit shift operation as much as a maximum phase level, and the OR operation may be performed by collecting vectors having a Hamming weight of 1 obtained through the shift operation.

The soft-decision decoding method may further comprise: performing a reprocessing operation together with the generating of the TEP, wherein the reprocessing operation may comprise: generating a codeword by using a K-bit most reliable basis (MRB) vector when a phase value of the input signal is 0 (Phase-0), generating the TEP having a Hamming weight L to perform an exclusive OR (XOR) operation with the K-bit MRB vector and generating a candidate codeword when the phase value is L (Phase-L).

According to a second exemplary embodiment of the present disclosure, a soft-decision decoding method used in a digital communication system may comprise: performing a Bose-Chadhuri-Hocquenghem (BCH) decoding process through a BCH decoder when an input codeword is input to a soft-decision decoder through an input message; determining whether a highest order of an error position equation generated in the BCH decoder is equal to a number of found solutions; returning a codeword decoded in the BCH decoder when the highest order is equal to the number of found solutions in the determining; and performing an ordered statistic decoding (OSD) algorithm to find a decoded codeword, when the highest order is not equal to the number of found solutions in the determining.

The finding of the decoded codeword may comprise: performing Gaussian elimination, and the performing of the Gaussian elimination may comprise: a setup operation of finding a pivot and an elimination operation of performing the Gaussian elimination after the setup operation.

The setup operation may comprise: importing a row stored in a row table or a row buffer by using a result sorted in a descending order in a sorter; searching for a pivot; determining whether K pivots are found; stopping a current setup operation when determining that the K pivots are found in the determining; and returning to the importing of the row and repeating the setup operation, when determining that the K pivots are not found in the determining.

The elimination operation may comprise: performing partial sorting by using an index and a reliability value stored in the setup operation; sequentially importing N rows from the row buffer in parallel to the performing of the partial sorting and performing Gaussian elimination; stopping a current elimination operation when N rows are output as a result of performing the Gaussian elimination; and arranging first K rows of output rows in a descending order in order of indices used for the partial sorting when the N rows are not output as the result of performing the Gaussian elimination, filling the rest with rows output from the row buffer to form the N rows, and performing the Gaussian elimination.

According to a third exemplary embodiment of the present disclosure, a soft-decision decoding apparatus used in a digital communication system may comprise: a hard-decision Bose-Chadhuri-Hocquenghem (BCH) decoder to be used as a stopping rule of ordered statistic decoding (OSD) before performing the OSD on an input signal; and a preprocessing architecture and a reprocessing architecture for performing the OSD when a highest order of an error position equation generated in the BCH decoder is not equal to a number of solutions found in the BCH decoder.

When the highest order of the error position equation is equal to the number of solutions, a codeword decoded in the BCH decoder may be returned.

The BCH decoder may comprise a syndrome calculation (SC) unit, a key equation solver (KES) unit, a Chien search (CS) unit, a BCH control unit, and the KES unit may generate the highest order of the error position equation, and the CS unit may find the number of solutions.

The preprocessing architecture may provide a vector and a matrix used for the OSD, and comprise a reliability generalization unit, a sorter, a Gaussian elimination (GE) unit, and a preprocessing control unit.

The GE unit may perform Gaussian elimination through a setup operation and an elimination operation, and find K pivots in the setup operation and perform the Gaussian elimination in the elimination operation performed after the setup operation, in performing the Gaussian elimination.

The sorter may arrange K rows required for the OSD by performing sorting simultaneously during the elimination operation.

The reprocessing architecture may perform decoding through candidate codeword generation and comprises a reprocessing (RE) unit, a test error pattern (TEP) unit, temporal registers, and a reprocessing control unit.

The TEP unit may generate a TEP of a target Hamming weight through a shift operation and an OR operation, the shift operation may comprise a 1-bit shift operation as much as a maximum phase level, and the OR operation may be performed by collecting vectors having a Hamming weight of 1 obtained through the shift operation.

The reprocessing operation may comprise: generating a codeword by using a K-bit most reliable basis (MRB) vector when a phase value of the input signal is 0 (Phase-0), generating the TEP having a Hamming weight L to perform an exclusive OR (XOR) operation with the K-bit MRB vector and generating a candidate codeword when the phase value is L (Phase-L).

A reprocessing operation of the reprocessing unit may be performed in parallel when the TEP unit generates the TEP.

The preprocessing architecture and the reprocessing architecture may be connected to each other by an interconnect network and connected to an external buffer through the interconnect network.

According to the present disclosure, an improved OSD algorithm optimized for hardware may be supported for ultra-low latency in the soft-decision decoding apparatus.

Moreover, according to the present disclosure, by executing a stopping rule using the hard-decision BCH decoder before executing the OSD algorithm, latency time may be greatly reduced in the soft-decision decoder.

In addition, according to the present disclosure, by improving an existing architecture, sorting may be performed simultaneously during execution of Gaussian elimination to generate a matrix suitable for the OSD algorithm, thereby providing improved Gaussian elimination where the soft-decision decoding method and apparatus may perform sorting at the same time without loss of latency time.

According to the present disclosure, the soft-decision decoding method and apparatus may be provided which support the reprocessing process of the OSD algorithm, thereby significantly reducing latency time while supporting the new OSD algorithm.

Furthermore, according to the present disclosure, the ultra-low-latency soft-decision decoding method and apparatus may be provided which are capable of using an ultra-reliable and low-latency communications (URLLC) service for a next-generation wireless communication system, industrial Intent of Things (IIoT), etc., and applicable to various environments requiring reliability of wireless communication data.

### BRIEF DESCRIPTION OF DRAWINGS

FIG. 1 is a block diagram of an ordered statistic decoding (OSD) hardware architecture.

FIGS. 2 and 3 are views for describing an operating principle of a stopping rule architecture applicable to the OSD hardware architecture of FIG. 1.

FIG. 4 is a block diagram of an overall architecture of a Gaussian elimination (GE) unit adoptable in the OSD hardware architecture of FIG. 1.

FIG. 5 is a view for describing an architecture of a pivot manager PM constituting the GE unit of FIG. 4.

FIGS. 6 and 7 are views showing a configuration of a PE adoptable in the PM of FIG. 5. FIG. 6 shows a pivot PE pPE. FIG. 7 shows a non-pivot PE nPE, especially, a second non-pivot PE.

FIG. 8 is a block diagram of a TEP unit adoptable in the OSD hardware architecture of FIG. 1.

FIG. 9 is a block diagram of an architecture of an RE unit adoptable in the OSD hardware architecture of FIG. 1.

FIGS. 10 and 11 are views showing an interworking process of the RE unit and the TEP unit of FIG. 9.

FIG. 12 is a graph showing error correction capabilities of a BCH code with a stopping rule and without a stopping rule in the OSD hardware architecture of FIG. 1 through comparison.

FIG. 13 is a graph showing a complexity of an OSD algorithm according to the embodiment applicable to the OSD hardware architecture of FIG. 1 and a complexity of an OSD algorithm of a comparative example through comparison.

FIG. 14 is a flowchart of an operating principle of a stopping rule adoptable in an OSD hardware architecture according to another embodiment of the present disclosure.

FIGS. 15 and 16 are flowcharts for describing an operating principle of a GE unit adoptable in an OSD hardware architecture according to another embodiment of the present disclosure.

### DETAILED DESCRIPTION OF THE EMBODIMENTS

Exemplary embodiments of the present disclosure are disclosed herein. However, specific structural and functional details disclosed herein are merely representative for purposes of describing exemplary embodiments of the present disclosure. Thus, exemplary embodiments of the present disclosure may be embodied in many alternate forms and should not be construed as limited to exemplary embodiments of the present disclosure set forth herein.

Accordingly, while the present disclosure is capable of various modifications and alternative forms, specific exemplary embodiments thereof are shown by way of example in the drawings and will herein be described in detail. It should be understood, however, that there is no intent to limit the present disclosure to the particular forms disclosed, but on the contrary, the present disclosure is to cover all modifications, equivalents, and alternatives falling within the spirit and scope of the present disclosure. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between,” “adjacent” versus “directly adjacent,” etc.).

The terminology used herein is for the purpose of describing particular exemplary embodiments only and is not intended to be limiting of the present disclosure. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the present disclosure will be described in greater detail with reference to the accompanying drawings. In order to facilitate general understanding in describing the present disclosure, the same components in the drawings are denoted with the same reference signs, and repeated description thereof will be omitted.

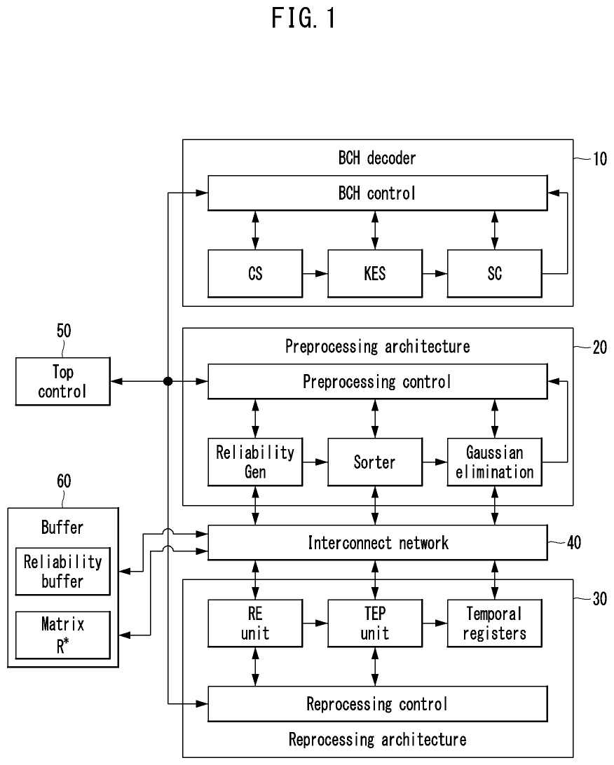

FIG. 1 is a block diagram of an ordered statistic decoding (OSD) hardware architecture.

Referring to FIG. 1, an OSD hardware architecture (hereinafter, referred to as a ‘soft-decision decoding apparatus’) may include a Bose-Chadhuri-Hocquenghem (BCH) decoder 10, a preprocessing architecture 20, and a reprocessing architecture 30.

The BCH decoder 10 may be responsible for a stopping rule. The BCH decoder 10 may include a syndrome calculation (SC) unit, a key equation solver (KES) unit, a Chien search (CS) unit, and a BCH control unit.

The preprocessing architecture 20 may provide a vector and a matrix used for an OSD algorithm. The preprocessing architecture 20 may include a reliability generalization unit, a sorter, a Gaussian elimination (GE) unit, and a preprocessing control unit.

The reprocessing architecture 30 may be responsible for decoding by generating a candidate codeword. The reprocessing architecture 30 may include a reprocessing (RE) unit, a test error pattern (TEP) unit, temporal registers, and a reprocessing control unit.

The preprocessing architecture 20 and the reprocessing architecture 30 may be connected to each other by an interconnect network 40 and may also be connected to an external buffer 60.

The BCH control unit, the preprocessing control unit, and the reprocessing unit may be connected to a top control unit 50 and may operate or transmit and receive data under control of the top control unit 50.

The external buffer 60 may include a reliability buffer and a matrix buffer. The matrix buffer may store matrix R*.

An example of the OSD algorithm adoptable for the soft-decision decoder according to the embodiment may be as follows:

[Algorithm 1]

| Input: Ĝ, â, ŷ, \hat{v} | | | |
|---|---|---|---|
| Output: π₁⁻¹(π₂⁻¹(cₒₚₜ)) | | | |
| Initialize: cₒₚₜ^{T} = Ğ\hat{v}^{T}, hₒₚₜ = â(cₒₚₜ ⊕ ŷ)^{T} | | | |
| Phase-l reprocessing: | | | |
| for l = 1 to lₘₐₓ do | | | |
| \| | for Q = 1 to ┌K/p┐ do | | |
| \| | \| | j = (K − 1) − Q × p | [symbol] Setting the boundary |

| \| | \| | ${h}_{dis} = ( {\sum }_{i = 0}^{K - 1} {e}_{i} \cdot {\hat{α}}_{i} ) ( 1 + ρ {\sum }_{i = K}^{N - 1} {\hat{α}}_{i} / {\sum }_{i = 0}^{K - 1} {\hat{α}}_{i} )$ | | |
|---|---|---|---|---|
| \| | \| | if hₒₚₜ < h_{dis} then Break | | |
| \| | \| | repeat | | |
| \| | \| | \| | c_{local}^{T} = Ĝ(\hat{v} ⊕ e)^{T} | [symbol] e: having l errors |

| | | | |
|---|---|---|---|
| \| | \| | \| | h_{local} = â(c_{local} ⊕ ŷ)^{T} |
| \| | \| | \| | if h_{local} < hₒₚₜ then |
| \| | \| | \| | cₒₚₜ = c_{local} and hₒₚₜ = h_{local} |
| \| | \| | \| | end |

| | | |
|---|---|---|
| \| | \| | until e is the last TEP of the Q-th segment |

| | |
|---|---|
| \| | end |

end

In the OSD algorithm according to the embodiment shown in Algorithm 1, Ĝ, â, ŷ, \hat{v} indicate a generator matrix, a reliability vector, an N-bit hard-decision vector, and a K-bit most reliable hard-decision vector, respectively. Copt indicates an optimum candidate codeword vector. Cₒₚₜ^{T} indicates a transposed optimum candidate codeword vector. l, Q, j, K and p respectively indicate a current phase level, a current segment number, a current segment boundary, a value of K of a code expressed as (N, K), and a size of a segment. h_{dis} indicates a segment discarding threshold. et indicates an i-th bit of a test error pattern. p indicates a local candidate codeword vector. C_{local}^{T} indicates a transposed local candidate codeword vector, and h_{local} indicates a local weighted Hamming distance.

As shown in Algorithm 1, to relax computing overhead without degrading error correction performance, the embodiment provides a cost-efficient OSD algorithm introducing basically two calculation two computational relaxation parameters, i.e., a fixed-size segment construction and an approximate discarding threshold.

The fixed-size segment construction may be determined according to the following principle. That is, by skipping a redundant segment without performing generation of a test error pattern (TEP), an average decoding time may be reduced when compared to existing OSD decoding. In this case, to prevent generation of a significant amount of computational overhead, numerous computationally intensive multiplication and division operations required to configure a next segment may be simplified. In addition, accurate computation of a boundary reliability value requires the use of a high-resolution arithmetic unit, further increasing processing complexity, such that a size of each segment may be set to a certain size p without calculating a correct segment size with time-consuming high-resolution computation. In the embodiment, p may be, but not limited to, the power of 2. As such, according to the embodiment, little redundant TEP generation occurs at a non-optimized segment size by completely eliminating complex boundary computation in terms of computational cost, and an address for accessing the next segment may be sorted in an on-chip buffer by limiting the segment size to a power of 2, thus relaxing segment import overhead.

The approximate discarding threshold may be determined according to the following principle. That is, in an existing technology, when a weighted Hamming distance is less than a discarding threshold, a process immediately moves to the following operation without executing the other segments. As such, in the existing technology, decoding efficiency may be improved by discarding a redundant segment, but obtaining the discarding threshold may cause a computational bottleneck phenomenon, especially due to multiple multiplication and division applications to obtain statistical information.

In the embodiment, as shown by the OSD algorithm of Table 1, an approximate threshold for significantly relaxing computational overhead required for all segment-level reprocessing may be induced. More specifically, in the embodiment, to approximate a threshold that is a product of a standard deviation of the reliability vector, a user-defined parameter, and K/(N-K), a discarding threshold may be simplified to the approximate discarding threshold by introducing a fixed user-defined parameter.

Meanwhile, the approximation threshold may be simplified to significantly eliminate complex computation in segmentation-discarding decoding (SDD), but the standard deviation of the reliability vector may change with a channel state and thus the use of a random approximate discarding threshold may affect a total correction capability. Thus, in the embodiment, to find a suitable approximate discarding threshold, a specific Eb/N0 condition for achieving a target block error rate (BLER) may be considered, and a hardware-friendly value close to an average of original threshold values may be selected.

As such, in the embodiment, the approximate discarding threshold may use segments of a number similar to the original SDD method to achieve the same target BLER requirements. In this case, more segments may be processed in a low-SNR region. Moreover, by setting the approximate discarding threshold to the hardware-friendly value, shift-and-add operations may be performed in application of the approximate discarding threshold, thereby further reducing processing cost.

As described above, the OSD algorithm according to the embodiment, which is a new OSD algorithm using reprocessing, may be used to greatly reduce latency time by being applied to a soft-decision decoder used in communication devices such as next-generation communication systems, industrial Internet of Things (IIoT), etc.

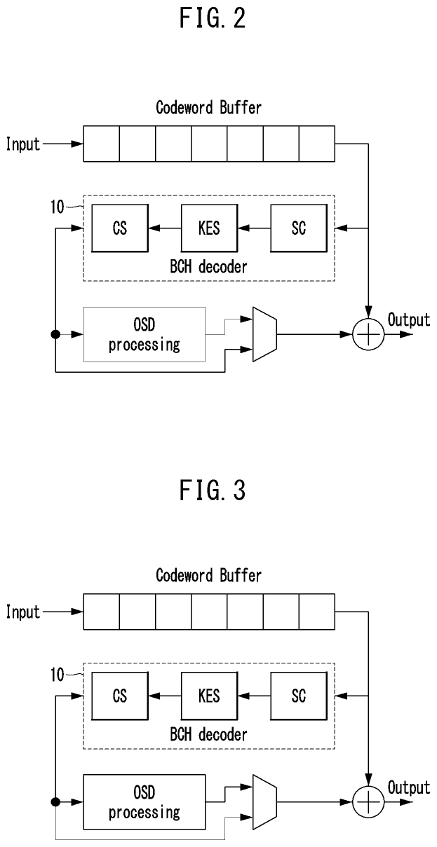

FIGS. 2 and 3 are views for describing an operating principle of a stopping rule architecture applicable to the OSD hardware architecture of FIG. 1.

FIG. 2 shows a stopping rule architecture in a partially activated state, and FIG. 3 shows a stopping rule architecture in a fully activated state.

The stopping rule architecture may include a BCH decoder and include a first signal processing path that passes through the BCH decoder and a second signal processing path that outputs an error-corrected codeword as a result value through the BCH decoder. An output of the first signal path and an output of the second signal path may be output through an adder.

The BCH decoder 10 may include one or more blocks for a syndrome calculation (SC) unit, a key equation solver (KES) unit, and a Chien search (CS) unit.

In the stopping rule architecture using the BCH decoder, when a codeword error input to the codeword buffer is corrected through the BCH decoder before execution of the OSD algorithm, a codeword completing decoding immediately without execution of the OSD algorithm may be output as a result value.

Moreover, when a highest order of an error-location polynomial generated in an operation of processing a KES block of a BCH decoding process is equal to the number of solutions found in an operation of processing a CS block, the BCH decoder may declare a decoding success and pass execution of the OSD algorithm without execution of the OSD algorithm (see FIG. 2).

Moreover, when a highest order of an error-location polynomial generated in an operation of processing a KES block of a BCH decoding process is different from the number of solutions found in an operation of processing a CS block, the BCH decoder may declare a decoding failure and perform OSD processing (see FIG. 3).

The output of the BCH decoder and the OSD processing result may be selectively delivered to the adder through a multiplexer (MUX), and may be generated as an output of a stopping rule architecture through the adder. The multiplexer may be a combinational circuit that generates a single output from multiple data inputs.

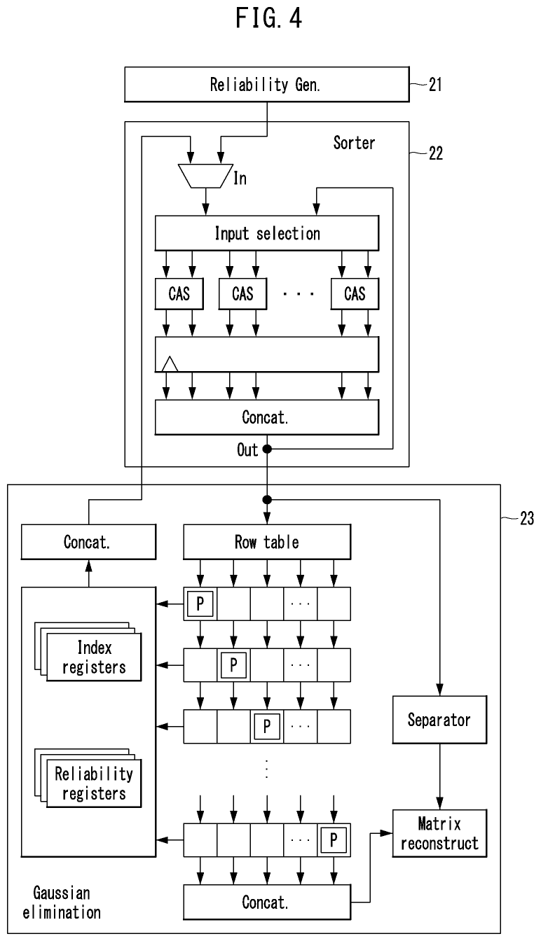

FIG. 4 is a block diagram of an overall architecture of a Gaussian elimination (GE) unit adoptable in the OSD hardware architecture of FIG. 1.

Referring to FIG. 4, a GE unit 23 may include blocks for a row table, concatenation (Concat.), a separator, matrix reconstruction, and registers. The registers may include index registers and reliability registers. The concatenation block may include a first concatenating block connected between a row table block and a matrix reconfiguration block and a second concatenating block arranged in an output terminal of a register block.

The row table of the GE unit 23 may receive data output from a sorter 22, and the output of the second concatenating block may be input to the sorter 22.

Herein, the sorter 22 may include an input-side (In) multiplexer, an input selection block, a compare and swap (CAS) circuit block, a register block, and a concatenating (Concat.) block. The register block may include a D-flipflop, etc., and may be configured to hold input data and output held data according to an externally input clock. The concatenating block may be arranged in an output side (Out).

The sorter 22 may be configured to receive data input from a reliability generalization unit 21 and data input from the GE unit 23 through a multiplexer and to input feedbacks of the output of the multiplexer and the output of the sorter to an input selection block in the sorter 22.

In the embodiment, the GE unit 23 may include K (random natural number) pivot managers PM. The GE unit 23 may perform Gaussian elimination through a setup operation and an elimination operation.

The GE unit 23 may find K pivots in the setup operation and perform Gaussian elimination in the elimination operation. The GE unit 23 may be configured to perform the elimination operation after the setup operation and to most reliably arrange K rows suitable for the OSD algorithm by performing sorting simultaneously during the elimination operation.

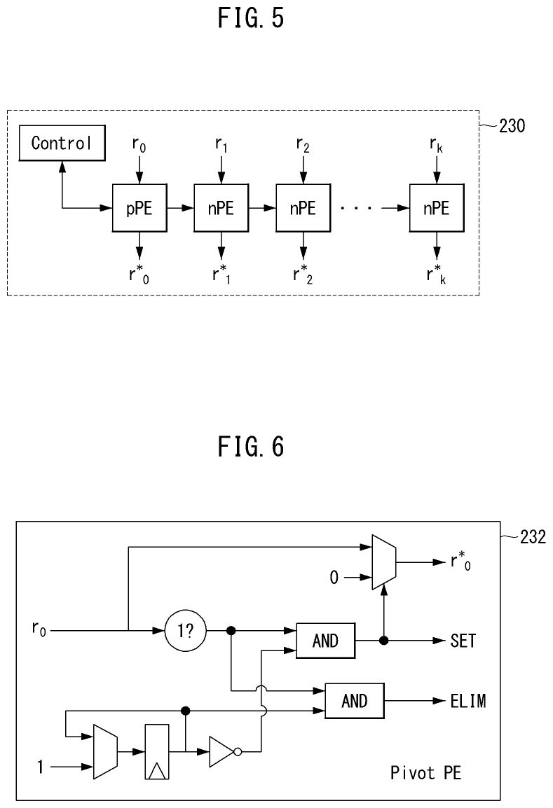

FIG. 5 is a view for describing an architecture of a pivot manager PM constituting the GE unit of FIG. 4.

Referring to FIG. 5, the pivot manager PM may include one pivot PE unit pPE and K non-pivot PE units nPE. The pivot PE may be connected to a control block in each PM, determine whether an input r₀ is 1 or not, and output an output r*₀.

Among the k non-pivot PEs nPE, a first non-pivot PE nPE connected to a pivot PE may combine an output of the pivot PE with an autonomous input r₁ to an autonomous output r*₁. Likewise, second to K non-pivot PEs nPE among K non-pivot PEs nPE may be arranged to sequentially deliver output values. Moreover, each of the second to K non-pivot PEs nPE may sequentially combine an output of the non-pivot PE nPE and each of autonomous inputs r₂ to rₖ to generate each of autonomous outputs r*₂ to r*ₖ.

According to the above-described configuration, a pPE included in an i-th(i is a natural number less than or equal to K) PM among K PMs included in the GE unit may operate to determine whether an i^{th} element of a row input to the corresponding PM is 1 or not and generate a detection signal upon finding 1 first to inform the outside that the pivot is found.

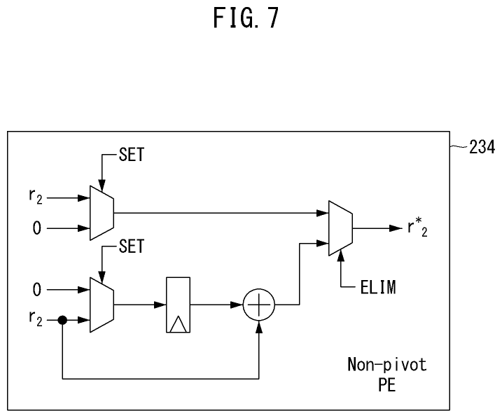

FIGS. 6 and 7 are views showing a configuration of a PE adoptable in the PM of FIG. 5. FIG. 6 shows a pivot PE pPE. FIG. 7 shows a non-pivot PE nPE, especially, a second non-pivot PE.

Referring to FIG. 6, a pivot PE 232 may be configured to proceed to a setup operation SET or an elimination operation ELIM according to whether input data r₀ is 1 or not (1?) and to output an output signal r*₀ as a detection signal detecting 1 in case of the setup operation.

To this end, the pivot PE 232 may include a multiplexer with two inputs of an active input 1 and autonomous feedback, a register block for holding an output of the multiplexer, and a feedback path connected from an output of the register block to an input of the multiplexer, and a combination of the multiplexer, the register block, and the feedback path may be referred to as an input module. The register block may be simply referred to as a register.

The pivot PE 232 may be configured to input the output of the register block, i.e., the output of the input module and the input data 1-0 to a second AND circuit, and input an inverted output of the input module, obtained by inverting the output of the input module through an inverter, and the input data r₀ to a first AND circuit.

According to the above-described configuration, the pivot PE 232 may identify whether the input data r₀ is 1 according to the output of the first AND circuit, thus cause the PM to proceed to the setup operation, and output an output signal r*₀ through the multiplexer that receives the input data r₀ and dummy input data 0. The pivot PE 232 may identify that the input data r₀ is not 1 based on the output of the second AND circuit, and thus cause the PM to proceed to the elimination operation.

Referring to FIG. 7, a second non-pivot PE 234 may include a first multiplexer, a second multiplexer, a register block an adder, and a third multiplexer. The first multiplexer may be configured to receive input data r₂ and dummy input data 0 and deliver the output to the third multiplexer. The first multiplexer may be activated or deactivated according to a signal output in the setup operation SET.

The second multiplexer may be configured to receive the input data r₂ and the dummy input data 0 and deliver the output to the register block. The output of the register block may be added to the input data r₂ in the adder and thus may be input to the third multiplexer. The second multiplexer may be activated or deactivated according to a level or existence/absence of a signal based on a processing result of the setup operation SET.

The third multiplexer may be configured to receive the output of the first multiplexer and the output of the adder as two inputs and to output the output signal r*₂. The third multiplexer may be activated or deactivated according to a processing result of the elimination operation ELIM.

While a second non-pivot PE 234 has been described in the embodiment, the structure or operating principle of the second non-pivot PE may also be equally applied to each of the third to kth non-pivot PEs.

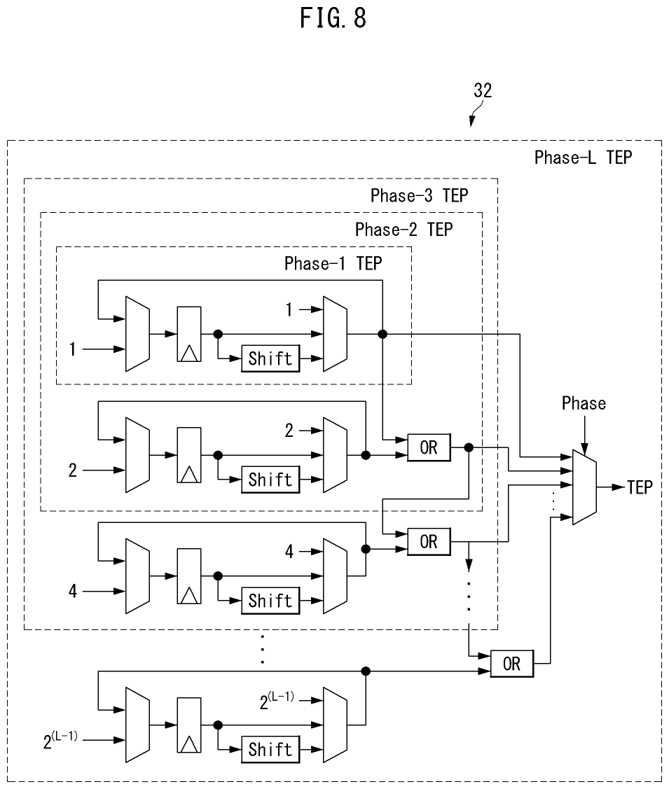

FIG. 8 is a block diagram of a TEP unit adoptable in the OSD hardware architecture of FIG. 1.

Referring to FIG. 8, a TEP unit 32 may generate a TEP. That is, the TEP unit 32 may include a unit that performs an 1-bit shift operation at a maximum phase level. The TEP unit 32 may collect vectors having a Hamming weight of 1 having undergone a shift operation, perform an OR operation, and output a TEP vector suitable for the current phase level as an output.

To this end, the TEP unit 32 may include a phase-1 TEP unit, a phase-2 TEP unit, a phase-3 TEP unit, and a phase-L TEP unit. L, which is a random natural number, may correspond to a maximum phase level.

The phase-1 TEP unit may include a first multiplexer that receives two inputs including a preset input 1 (=20) and a self-feedback input, a register that holds an output of the first multiplexer, a shift block that receives an output of the register, and a second multiplexer. The second multiplexer may receive three inputs including the preset input 1 (=20), the output of the register, and an output of the shift block and generate one output. The output of the second multiplexer may be input to the first multiplexer as a feedback input.

The phase-2 TEP unit may include substantially the same components as those of the phase-1 TEP unit, and may further include a first OR block that performs an OR operation on the output of the phase-1 TEP unit and the output of the phase-2 TEP unit. The first multiplexer and the second multiplexer of the phase-2 TEP unit may have a preset input 2 (=21) as several inputs.

The phase-3 TEP unit may include substantially the same components as those of the phase-2 TEP unit. Herein, a second OR block included in the phase-3 TEP unit may be configured to perform the OR operation on the output of the phase-3 TEP unit and the output of the first OR block. The first multiplexer and the second multiplexer of the phase-3 TEP unit may have a preset input 4 (=22) as several inputs.

The phase-L TEP unit may include substantially the same components as those of the phase-2 TEP unit. Herein, an (L-1)th OR block included in the phase-L TEP unit may be configured to perform the OR operation on the output of the phase-3 TEP unit and the output of the second OR block. The first multiplexer and the second multiplexer of the phase-L TEP unit may have a preset input (2^{L-1}) as several inputs.

The phase-L TEP unit may further include an output-terminal multiplexer having the output of the phase-1 TEP unit, the output of the first OR block, the output of the second OR block, and the output of the (L-1)th OR block as a plurality of inputs.

In the embodiment, L may be a natural number equal to or greater than 4, and when L is 5 or greater, at least one phase TEP unit may be added between the phase-3 TEP unit and the phase-L TEP unit. As such, the above-described structure of the TEP unit may have a flexibly extensible structure according to a maximum phase level or a maximum phase value.

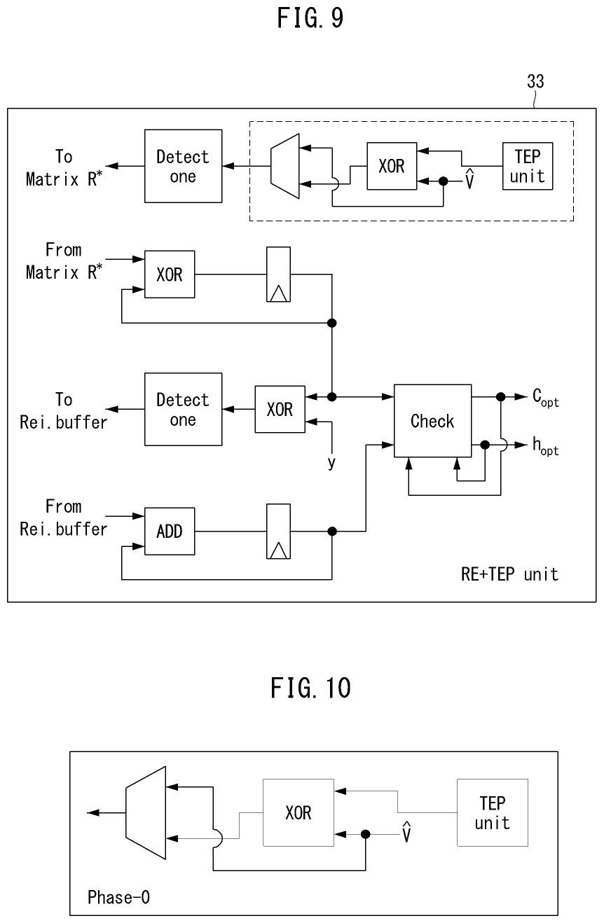

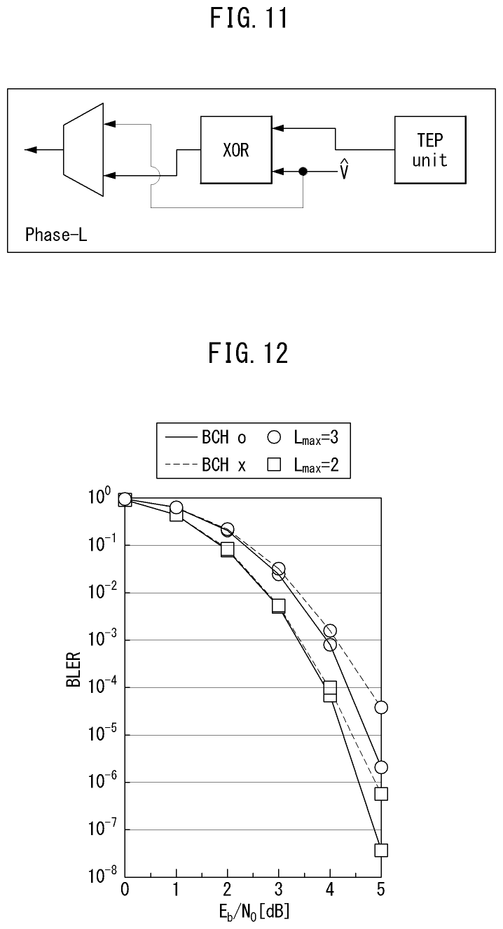

FIG. 9 is a block diagram of an architecture of an RE unit adoptable in the OSD hardware architecture of FIG. 1. FIGS. 10 and 11 are views showing an interworking process of the RE unit and the TEP unit of FIG. 9.

Referring to FIG. 9, an RE unit 33 may perform a reprocessing operation in an OSD algorithm. To this end, the RE unit 33 may include a first detect one block, a first exclusive OR (XOR) operation block, a first register, a second XOR operation block, a second detect one block, an addition (ADD) block, a second register, and a check block.

The first detect one block may receive an output of a TEP unit together with an input of a most reliable basis (MRB) vector v and perform an XOR operation thereon, and receive an output signal of a multiplexer with two inputs including a result of the XOR operation and the MRB vector. An output of the first detect one block may be stored in a matrix R* generated in a buffer in a soft-decision decoder.

The first XOR operation block may receive two inputs including an input from the matrix R* and the output of the first register and perform the XOR operation thereon. The result of the XOR operation of the first XOR operation block may be delivered to the first register and held, and may be output in the first register according to a clock signal.

The second XOR operation block may receive two inputs including the output of the first register and a certain input y and perform the XOR operation thereon. The output of the second XOR operation block may be input to the second detect one block, the output of which may be stored in a reliability (Rel.) buffer in the buffer of the soft-decision decoder.

The addition (ADD) block may receive two inputs including an input from the Rel. buffer and the output of the second register and perform the addition operation thereon. The output of the addition block may be delivered to the second register and held, and may be output in the second register according to a clock signal.

The check block may receive the output of the first register and the output of the second register and perform a check operation, and then output an optimal codeword Copt and an optimal Hamming weight hopt. In this case, the optimal codeword Copt and the optimal Hamming weight hopt output from the check block may be used as other inputs of the check block.

The above-described RE unit 33 may operate with the TEP unit (see 32 of FIG. 8), and when a phase value is 0 (Phase-0) as shown in FIG. 10, a codeword may be generated using a K-bit MRB vector Q. In this case, the TEP unit may be deactivated. The generated codeword may be used to calculate a weighted Hamming distance by comparison with an input soft-decision vector.

The RE unit 33 may operate with the TEP unit, and when the phase value is L (Phase-L) as shown in FIG. 11, a TEP with a Hamming weight of L may be generated and undergoes an XOR operation with the K-bit MRB vector to generate a candidate codeword.

The RE unit 33 may calculate the weighted Hamming distance in this way, thereby continuously updating the optimal codeword.

FIG. 12 is a graph showing error correction capabilities of a BCH code with a stopping rule and without a stopping rule in the OSD hardware architecture of FIG. 1 through comparison.

In FIG. 12, a block error rate (BLER) may be calculated according to a value dB obtained by dividing bad blocks E_{b} by total blocks No (E_{b}/N₀). A block may correspond to a block code.

As shown in FIG. 12, in each of a case where the Hamming weight L is 2 (Lₘₐₓ=2) at most and a case where the Hamming weight L is 3 (Lₘₐₓ=3) at most in the soft-decision decoder, a BCH decoder may be used for a stopping rule in the embodiment (a solid line, BCH is used (BCH o)), and thus it may be seen that the error correction capability is improved. Herein, a soft-decision decoder of a comparative example (a dotted line, BCH is not used (BCH x)) may have the same architecture as in the embodiment except for the BCH decoder.

For reference, it is widely known that a general BCH decoder, which is a low-complexity decoder, unconditionally corrects t errors or less, but when the number of errors in the K-bit MRB vector of the OSD algorithm is greater than a maximum phase value, corresponding errors may not be corrected. Herein, t may be a number corresponding to an error correction capability of the BCH decoder.

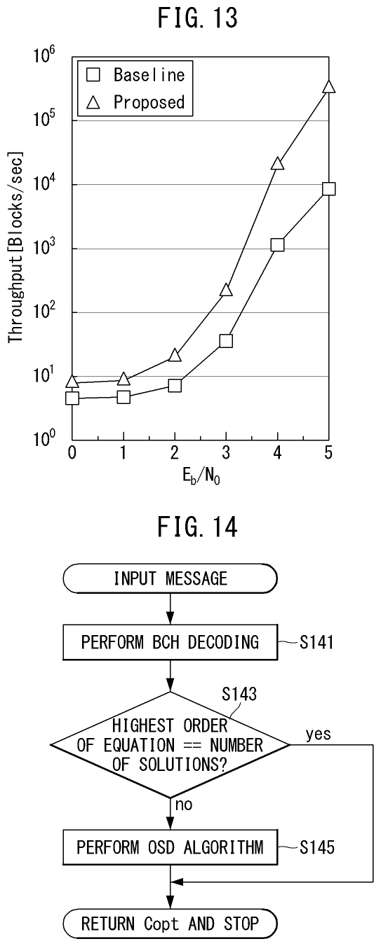

FIG. 13 is a graph showing a complexity of an OSD algorithm according to the embodiment applicable to the OSD hardware architecture of FIG. 1 and a complexity of an OSD algorithm of a comparative example through comparison.

FIG. 13 is a diagram for comparing throughputs, i.e., the number of block codes processible per unit time (blocks/sec) when an OSD hardware architecture, i.e., a soft-decision decoder is implemented in a field programmable gate array (FPGA) operating at 100 MHz.

Referring to FIG. 13, a comparative example (Baseline) is structured such that existing Gaussian elimination is used and a stopping rule is not applied, and it may be seen that when an architecture of the embodiment (Proposed) is used, the number of block codes processible per unit time increases 40 times or more compared to the comparative example.

FIG. 14 is a flowchart of an operating principle of a stopping rule adoptable in an OSD hardware architecture according to another embodiment of the present disclosure.

Referring to FIG. 14, when an input codeword is input to a soft-decision decoder through an input message, a BCH decoding process is performed through a BCH decoder in operation S141.

Next, when the highest order of an error position equation generated in the BCH decoder is equal to the number of found solutions (yes in operation S143), it may be a case where the BCH decoder succeeds in decoding, and thus a decoded codeword is immediately returned. In this case, the decoded codeword may correspond to an optimal candidate codeword vector Copt.

Meanwhile, when the highest order of the error position equation generated in the BCH decoder is not equal to the number of found solutions (no in operation S143), the OSD algorithm may be performed to find the decoded codeword in operation S145.

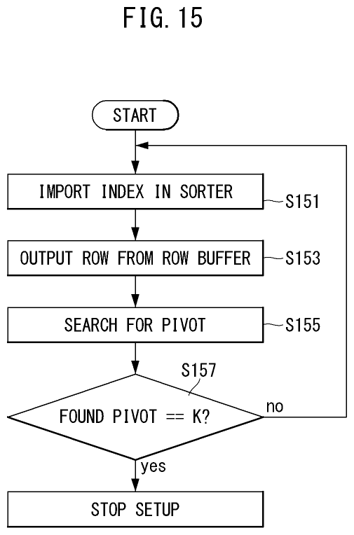

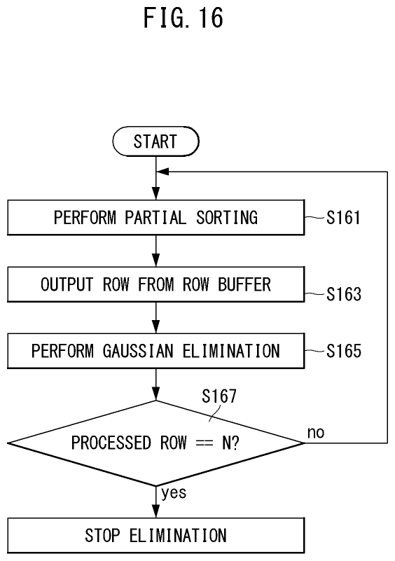

FIGS. 15 and 16 are flowcharts for describing an operating principle of a GE unit adoptable in an OSD hardware architecture according to another embodiment of the present disclosure.

To describe a setup operation to be executed with reference to FIG. 15, a sorter in a preprocessing architecture of an OSD hardware architecture may import a row stored in a row table or a row buffer by using results sorted in a descending order. Herein, the row may correspond to an index in operation S151.

Next, the row may be output from the row buffer in operation S153.

Next, the setup operation may be performed until K pivots are found, and the pivot may be searched for, in operation S155.

When the K pivots are found (yes in operation S157), the current setup operation may be stopped. Meanwhile, when the K pivots may not be found for a preset time or a number of repetitions (no of operation S157), the process returns to the operation of importing a row stored in the row buffer and repeats the setup operation.

Referring to FIG. 16, in the elimination operation, partial sorting may be performed using an index and a reliability value stored in the setup operation, in operation S161.

At the same time, N rows may be sequentially imported from the row buffer in operation S163 and Gaussian elimination may be performed in operation S165.

When the N rows are output (yes of operation S167), the elimination operation may be stopped.

When the N rows are not output (no of operation S167), first K rows of the output rows may be arranged in a descending order in order of indices output through previous partial sorting and the others may be filled with the rows output from the row buffer to form N rows, and then Gaussian elimination may be performed.

According to the above-described embodiment, a new OSD hardware architecture using a soft-decision BCH decoder as a stopping rule before execution of an OSD algorithm may be provided.

In addition, a soft-decision decoder architecture may be provided which performs Gaussian elimination simultaneously with a sorter.

Moreover, a TEP unit capable of flexibly extending an architecture according to a maximum phase value to generate a TEP and generating a TEP through a shift operation and an OR operation, and a soft-decision decoder including the TEP unit may be provided.

According to the embodiment, there may be provided a scheme to perform reprocessing through interworking between an RE unit and the TEP unit in a reprocessing process of the OSD algorithm and a soft-decision decoder using the scheme.

An apparatus according to the embodiment corresponding to the new OSD hardware architecture or soft-decision decoder described above may include an FPGA-based architecture. Moreover, the apparatus may include at least one processor.

In this case, the processor may include the BCH decoder, the preprocessing architecture, the reprocessing architecture, the interconnect network, the top control unit, the buffer, described with reference to FIG. 1, or a combination thereof.

Moreover, the processor may execute a program command stored in at least any one of the memory and the storage device. The program command may include at least one command for implementing the above-described soft-decision decoding method. By such at least one command, the processor may be configured to perform an operation of using a hard-decision BCH decoder as a stopping rule of an OSD before performing the OSD on an input signal, and an operation of performing the OSD when the highest order of an error position equation generated in the BCH decoder is not equal to the number of solutions found in the BCH decoder.

The aforementioned processor may refer to a central processing unit (CPU), a graphics processing unit (GPU), or a dedicated processor on which at least one method among methods according to the exemplary embodiments of the present disclosure is performed. Also, each of the memory and the storage device may include at least one of a volatile storage medium and a non-volatile storage medium. For example, the memory may be configured as at least one of a read only memory (ROM) and a random access memory (RAM).

The operations of the method according to the exemplary embodiment of the present disclosure can be implemented as a computer readable program or code in a computer readable recording medium. The computer readable recording medium may include all kinds of recording apparatus for storing data which can be read by a computer system. Furthermore, the computer readable recording medium may store and execute programs or codes which can be distributed in computer systems connected through a network and read through computers in a distributed manner.

The computer readable recording medium may include a hardware apparatus which is specifically configured to store and execute a program command, such as a ROM, RAM or flash memory. The program command may include not only machine language codes created by a compiler, but also high-level language codes which can be executed by a computer using an interpreter.

Although some aspects of the present disclosure have been described in the context of the apparatus, the aspects may indicate the corresponding descriptions according to the method, and the blocks or apparatus may correspond to the steps of the method or the features of the steps. Similarly, the aspects described in the context of the method may be expressed as the features of the corresponding blocks or items or the corresponding apparatus. Some or all of the steps of the method may be executed by (or using) a hardware apparatus such as a microprocessor, a programmable computer or an electronic circuit. In some embodiments, one or more of the most important steps of the method may be executed by such an apparatus.

In some exemplary embodiments, a programmable logic device such as a field-programmable gate array may be used to perform some or all of functions of the methods described herein. In some exemplary embodiments, the field-programmable gate array may be operated with a microprocessor to perform one of the methods described herein. In general, the methods are preferably performed by a certain hardware device.

The description of the disclosure is merely exemplary in nature and, thus, variations that do not depart from the substance of the disclosure are intended to be within the scope of the disclosure. Such variations are not to be regarded as a departure from the spirit and scope of the disclosure. Thus, it will be understood by those of ordinary skill in the art that various changes in form and details may be made without departing from the spirit and scope as defined by the following claims.

What is claimed is:

1. A soft-decision decoding method used in a digital communication system, the soft-decision decoding method comprising:
using a hard-decision Bose-Chadhuri-Hocquenghem (BCH) decoder as a stopping rule of ordered statistic decoding (OSD) before performing the OSD on an input signal; and
performing the OSD when a highest order of an error position equation generated in the BCH decoder is not equal to a number of solutions found in the BCH decoder.

2. The soft-decision decoding method of claim 1, wherein
the performing of the OSD comprises performing Gaussian elimination through a setup operation and an elimination operation, and
the performing of the Gaussian elimination comprises finding K pivots in the setup operation and performing the Gaussian elimination in the elimination operation, wherein the elimination operation is performed after the setup operation.

3. The soft-decision decoding method of claim 2, further comprising arranging K rows required for the OSD by performing sorting through a sorter simultaneously during the elimination operation.

4. The soft-decision decoding method of claim 3, further comprising generating a test error pattern (TEP),
wherein the generating of the TEP comprises a TEP of a target Hamming weight through a shift operation and an OR operation,
the shift operation comprises a 1-bit shift operation as much as a maximum phase level, and
the OR operation is performed by collecting vectors having a Hamming weight of 1 obtained through the shift operation.

5. The soft-decision decoding method of claim 4, further comprising performing a reprocessing operation together with the generating of the TEP,
wherein the reprocessing operation comprises generating a codeword by using a K-bit most reliable basis (MRB) vector when a phase value of the input signal is 0 (Phase-0), generating the TEP having a Hamming weight L to perform an exclusive OR (XOR) operation with the K-bit MRB vector and generating a candidate codeword when the phase value is L (Phase-L).

6. A soft-decision decoding method used in a digital communication system, the soft-decision decoding method comprising:
performing a Bose-Chadhuri-Hocquenghem (BCH) decoding process through a BCH decoder when an input codeword is input to a soft-decision decoder through an input message;
determining whether a highest order of an error position equation generated in the BCH decoder is equal to a number of found solutions;
returning a codeword decoded in the BCH decoder when the highest order is equal to the number of found solutions in the determining; and
performing an ordered statistic decoding (OSD) algorithm to find a decoded codeword, when the highest order is not equal to the number of found solutions in the determining.

7. The soft-decision decoding method of claim 6, wherein
the finding of the decoded codeword comprises performing Gaussian elimination, and
the performing of the Gaussian elimination comprises a setup operation of finding a pivot and an elimination operation of performing the Gaussian elimination after the setup operation.

8. The soft-decision decoding method of claim 7, wherein
the setup operation comprises:
importing a row stored in a row table or a row buffer by using a result sorted in a descending order in a sorter;
searching for a pivot;
determining whether K pivots are found;
stopping a current setup operation when determining that the K pivots are found in the determining; and
returning to the importing of the row and repeating the setup operation, when determining that the K pivots are not found in the determining.

9. The soft-decision decoding method of claim 8, wherein
the elimination operation comprises:
performing partial sorting by using an index and a reliability value stored in the setup operation;
sequentially importing N rows from the row buffer in parallel to the performing of the partial sorting and performing Gaussian elimination;
stopping a current elimination operation when N rows are output as a result of performing the Gaussian elimination; and
arranging first K rows of output rows in a descending order in order of indices used for the partial sorting when the N rows are not output as the result of performing the Gaussian elimination, filling the rest with rows output from the row buffer to form the N rows, and performing the Gaussian elimination.

10. A soft-decision decoding apparatus used in a digital communication system, the soft-decision decoding apparatus comprising:
a hard-decision Bose-Chadhuri-Hocquenghem (BCH) decoder to be used as a stopping rule of ordered statistic decoding (OSD) before performing the OSD on an input signal; and
a preprocessing architecture and a reprocessing architecture for performing the OSD when a highest order of an error position equation generated in the BCH decoder is not equal to a number of solutions found in the BCH decoder.

11. The soft-decision decoding apparatus of claim 10, wherein, when the highest order of the error position equation is equal to the number of solutions, a codeword decoded in the BCH decoder is returned.

12. The soft-decision decoding apparatus of claim 10, wherein the BCH decoder comprises a syndrome calculation (SC) unit, a key equation solver (KES) unit, a Chien search (CS) unit, a BCH control unit, and
the KES unit generates the highest order of the error position equation, and
the CS unit finds the number of solutions.

13. The soft-decision decoding apparatus of claim 10, wherein the preprocessing architecture provides a vector and a matrix used for the OSD, and comprises a reliability generalization unit, a sorter, a Gaussian elimination (GE) unit, and a preprocessing control unit.

14. The soft-decision decoding apparatus of claim 13, wherein the GE unit performs Gaussian elimination through a setup operation and an elimination operation, and
finds K pivots in the setup operation and performs the Gaussian elimination in the elimination operation performed after the setup operation, in performing the Gaussian elimination.

15. The soft-decision decoding apparatus of claim 14, wherein the sorter arranges K rows required for the OSD by performing sorting simultaneously during the elimination operation.

16. The soft-decision decoding apparatus of claim 10, wherein the reprocessing architecture performs decoding through candidate codeword generation and comprises a reprocessing (RE) unit, a test error pattern (TEP) unit, temporal registers, and a reprocessing control unit.

17. The soft-decision decoding apparatus of claim 16, wherein the TEP unit generates a TEP of a target Hamming weight through a shift operation and an OR operation,
the shift operation comprises a 1-bit shift operation as much as a maximum phase level, and
the OR operation is performed by collecting vectors having a Hamming weight of 1 obtained through the shift operation.

18. The soft-decision decoding apparatus of claim 17, wherein the reprocessing operation comprises generating a codeword by using a K-bit most reliable basis (MRB) vector when a phase value of the input signal is 0 (Phase-0), generating the TEP having a Hamming weight L to perform an exclusive OR (XOR) operation with the K-bit MRB vector and generating a candidate codeword when the phase value is L (Phase-L).

19. The soft-decision decoding apparatus of claim 18, wherein a reprocessing operation of the reprocessing unit is performed in parallel when the TEP unit generates the TEP.

20. The soft-decision decoding apparatus of claim 10, wherein the preprocessing architecture and the reprocessing architecture are connected to each other by an interconnect network and connected to an external buffer through the interconnect network.
